(19) United States
(12) Patent Application Publication
(10) Pub. No.: US 2025/0197138 A1
(43) Pub. Date: Jun. 19, 2025

(54) ASSEMBLY FOR FLOATING SUBSTRATE, APPARATUS FOR PROCESSING SUBSTRATE HAVING THE SAME, AND METHOD FOR PROCESSING SUBSTRATE

(71) Applicant: SEMES CO., LTD., Cheonan-si (KR)

(72) Inventors: Eonseok LEE, Cheonan-si (KR); Boramchan SUNG, Asan-si (KR)

(73) Assignee: SEMES CO., LTD., Cheonan-si (KR)

(21) Appl. No.: 18/950,602

(22) Filed: Nov. 18, 2024

(30) Foreign Application Priority Data
Dec. 14, 2023 (KR) 10-2023-0182444

(51) Int. Cl. B65G 51/03; B08B 3/08; B65G 43/08; G03F 7/30

(52) U.S. Cl. CPC B65G 51/03; B08B 3/08; B65G 43/08; G03F 7/30; B65G 2203/0233

(57) ABSTRACT

An assembly for floating substrate includes: a floating stage including an upper plate facing a substrate and a nozzle plate provided under the upper plate to be divided into at least two portions in a same direction as a transfer direction of the substrate, a floating force supply unit configured to supply a floating force for floating the substrate to the upper plate through each of the nozzle plate divided into at least two portions, and a floating force adjustment unit configured to adjust magnitude of a floating force supplied to the at least two portions of the nozzle plate according to floating height at which the substrate is floating from the floating stage, a transfer unit configured to transfer the substrate floating on the floating stage along the floating stage, and a discharge unit configured to discharge chemical solution on the substrate transferred along the floating stage by the transfer unit.

### CROSS-REFERENCE TO RELATED APPLICATION(S)

This application claims priority to and benefits of Korean Patent Application No. 10-2023-0182444 under 35 U.S.C. § 119, filed on Dec. 14, 2023, in the Korean Intellectual Property Office (KIPO), the entire contents of which are incorporated herein by reference.

### BACKGROUND

### 1. Technical Field

Embodiments relate to an assembly for floating substrate, an apparatus for processing substrate including the same, and a method for processing substrate. More particularly, embodiments relate to an assembly capable of adjusting magnitude of floating force supplied to floating stage, an apparatus for processing substrate including the same, and a method for processing substrate.

### 2. Description of the Related Art

In manufacture of display element such as OLED and QLED, a discharge process of discharging a chemical solution such as a photosensitive solution, a developer, a cleaning solution, and/or the like, on a substrate may be performed. The discharge process may be mainly performed while the substrate is floating, and may be mainly performed by using an assembly for floating a substrate provided with a floating stage that supplies a floating force capable of floating the substrate.

As the floating stage in a discharge section in which the chemical solution is discharged on the substrate needs to be relatively accurately controlled, the floating stage may be provided to float the substrate by supplying a vacuum together with air to the substrate.

When performing the chemical solution discharge process using the floating stage, a floating force should be uniformly supplied to an entire area of the floating stage. If the floating force is supplied differently to some of the entire area of the floating stage, floating height of the substrate in the area may be different from floating height of other areas, and as a result, it may cause a defect according to performance of the chemical solution discharge process

### SUMMARY

Embodiments provide an assembly for floating substrate capable of uniformly supplying a floating force to an entire area of the floating stage.

Embodiments provide an apparatus for processing substrate including the assembly for floating substrate capable of uniformly supplying a floating force to an entire area of the floating stage.

Embodiments provide a method for processing substrate using the apparatus for processing substrate including the assembly for floating substrate capable of uniformly supplying a floating force to an entire area of the floating stage.

An assembly for floating substrate according to embodiments may include a floating stage including an upper plate facing a substrate and a nozzle plate provided under the upper plate to be divided into at least two portions in a same direction as a transfer direction of the substrate, a floating force supply unit configured to supply a floating force for floating the substrate to the upper plate through each of the nozzle plate divided into at least two portions, and a floating force adjustment unit configured to adjust magnitude of a floating force supplied to at least two portions of the nozzle plate according to floating height at which the substrate is floating from the floating stage.

In embodiments, the floating force supply unit is an air supply unit that supplies the air so that the substrate floats from the floating stage.

In embodiments, the assembly may further include a vacuum supply unit configured to supply vacuum to the floating stage so that the substrate can float from the floating stage.

In embodiments, the floating force supply unit may include branch tubes branched from a single tube to each of at least two portions of the nozzle plate, and the floating force adjustment unit is provided in each of the branch tubes.

An apparatus for processing substrate according to embodiments may include an assembly for floating substrate including a floating stage including an upper plate facing a substrate and a nozzle plate provided under the upper plate to be divided into at least two portions in a same direction as a transfer direction of the substrate, a floating force supply unit configured to supply a floating force for floating the substrate to the upper plate through each of the nozzle plate divided into at least two portions, and a floating force adjustment unit configured to adjust magnitude of a floating force supplied to at least two portions of the nozzle plate according to floating height at which the substrate is floating from the floating stage, a transfer unit configured to transfer the substrate floating on the floating stage along the floating stage, and a discharge unit configured to discharge chemical solution on the substrate transferred along the floating stage by the transfer unit.

In embodiments, the floating force supply unit is an air supply unit that supplies the air so that the substrate floats from the floating stage.

In embodiments, the apparatus may further include a vacuum supply unit configured to supply vacuum to the floating stage so that the substrate can float from the floating stage.

In embodiments, the floating force supply unit may include branch tubes branched from a single tube to each of at least two portions of the nozzle plate, and the floating force adjustment unit is provided in each of the branch tubes.

In embodiments, the apparatus may further include a sensing unit configured to sense floating height at which the substrate is floating from the floating stage, and a control unit configured to control the floating force adjustment unit to adjust magnitude of a floating force supplied to at least two portions of the nozzle plate based on sensing result from the sensing unit.

In embodiments, the sensing unit may be provided on the discharge unit, and is provided to be located vertically facing the substrate.

In embodiments, the discharge unit may be provided to discharge the chemical solution while moving in a direction perpendicular to a transfer direction of the substrate.

In embodiments, the apparatus may further include a carrying-in stage provided at entrance side of the floating stage so that the substrate can be carried into the floating stage, and a carrying-out stage provided at outlet side of the floating stage so that the substrate can be carried out from the floating stage.

In embodiments, rise of the substrate in the carrying-in stage and the carrying-out stage may be made by supplying air to the carrying-in stage and the carrying-out stage.

A method for processing substrate according to embodiments may include floating a substrate from a floating stage including an upper plate facing the substrate and a nozzle plate provided under the upper plate to be divided into at least two portions in a same direction as a transfer direction of the substrate, transferring the substrate along the floating stage, discharging chemical solution onto the substrate that is transported along the floating stage, and adjusting magnitude of a floating force supplied to each of at least two portions of the nozzle plate according to floating height at which the substrate floats from the floating stage.

In embodiments, the method may further include sensing the floating height at which the substrate floats from the floating stage.

In embodiments, the magnitude of the floating force supplied to each of at least two portions of the nozzle plate may be adjusted based on sensing result.

In embodiments, the sensing of the floating height may be performed on side of the discharge unit vertically facing the substrate.

In embodiments, the chemical solution may be discharged along a direction perpendicular to the transfer direction of the substrate.

In embodiments, the adjusting the magnitude of the adjusting force may be performed after a substrate on which the chemical solution has been discharged is carried out from the floating stage and before a substrate on which the chemical solution is to be discharged is carried in to the floating stage.

In embodiments, the substrate may be provided to float from the floating stage by supply of air and vacuum, and the magnitude of the floating force is adjusted by adjusting supply of air.

In embodiments, air to at least two portions of the nozzle plate may be supplied through different paths.

As the assembly for floating substrate, the apparatus for processing substrate, and the method of processing substrate according to embodiments may be configured to uniformly supply a floating force over an entire area of the floating stage, a process defect caused by varying floating height of the substrate in the floating stage, in particular, a process defect caused by performing a chemical solution discharge process may be prevented. Accordingly, the assembly for floating substrate, the apparatus for processing substrate, and the method of processing substrate according to embodiments may be expected to improve process reliability of manufacturing of a display element.

### BRIEF DESCRIPTION OF THE DRAWINGS

Illustrative, non-limiting embodiments will be more clearly understood from the following detailed description in conjunction with the accompanying drawings.

FIG. 1 is a schematic diagram for describing an apparatus for processing substrate according to embodiments.

FIG. 2 is a schematic diagram for describing a transfer unit in the apparatus for processing substrate according to embodiments.

FIG. 3 is a schematic diagram for describing a floating stage in the assembly for floating substrate of the apparatus for processing substrate according to embodiments.

FIGS. 4 and 5 are schematic diagrams for describing the assembly for floating substrate of the apparatus for processing substrate according to embodiments.

### DETAILED DESCRIPTION OF THE EMBODIMENTS

In the following description, for the purposes of explanation, numerous specific details are set forth in order to provide a thorough understanding of various embodiments or implementations of the disclosure. As used herein “embodiments” and “implementations” are interchangeable words that are non-limiting examples of devices or methods disclosed herein. It is apparent, however, that various embodiments may be practiced without these specific details or with one or more equivalent arrangements. Here, various embodiments do not have to be exclusive nor limit the disclosure. For example, specific shapes, configurations, and characteristics of an embodiment may be used or implemented in another embodiment.

The use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified. Further, in the accompanying drawings, the size and relative sizes of elements may be exaggerated for clarity and/or descriptive purposes. When an embodiment may be implemented differently, a specific process order may be performed differently from the described order. For example, two consecutively described processes may be performed substantially at the same time or performed in an order opposite to the described order. Also, like reference numerals denote like elements.

Unless otherwise specified, the illustrated embodiments are to be understood as providing features of the disclosure. Therefore, unless otherwise specified, the features, components, modules, layers, films, panels, regions, and/or aspects, etc. (hereinafter individually or collectively referred to as “elements”), of the various embodiments may be otherwise combined, separated, interchanged, and/or rearranged without departing from the scope of the disclosure.

Although the terms “first,” “second,” etc. may be used herein to describe various elements, these elements should not be limited by these terms. These terms are used to distinguish one element from another element. Thus, a first element discussed below could be termed a second element without departing from the teachings of the disclosure.

When an element, such as a layer, is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements. Further, the axis of the first direction DR1, the axis of the second direction DR2, and the axis of the third direction DR3 are not limited to three axes of a rectangular coordinate system, such as the X, Y, and Z-axes, and may be interpreted in a broader sense. For example, the axis of the first direction DR1, the axis of the second direction DR2, and the axis of the third direction DR3 may be perpendicular to one another, or may represent different directions that are not perpendicular to one another. For the purposes of this disclosure, “at least one of A and B” may be construed as A only, B only, or any combination of A and B. Also, “at least one of X, Y, and Z” and “at least one selected from the group consisting of X, Y, and Z” may be construed as X only, Y only, Z only, or any combination of two or more of X, Y, and Z. As used herein, the term “and/or” includes any and all combinations of one or more of the associated listed items.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof. Spatially relative terms, such as “beneath,” “below,” “under, “lower,” “above,” “upper,” “over,” “higher,” “side” and the like may be used herein for descriptive purposes, and thereby, to describe one element's relationship to another element(s) as illustrated in the drawings. Spatially relative terms are intended to encompass different orientations of an apparatus in use, operation, and/or manufacture in addition to the orientation depicted in the drawings. For example, if the device in the drawings is turned over, elements described as “below” or “beneath” other elements or features would then be oriented “above” the other elements or features. Thus, the term “below” can encompass both an orientation of above and below. Furthermore, the apparatus may be otherwise oriented (e.g., rotated 90 degrees or at other orientations), and, as such, the spatially relative descriptors used herein should be interpreted accordingly.

Various embodiments are described herein with reference to sectional and/or exploded illustrations that are schematic illustrations of embodiments and/or intermediate structures. As such, variations from the shapes of the illustrations as a result, for example, of manufacturing techniques and/or tolerances, are to be expected. Thus, embodiments disclosed herein should not necessarily be construed as limited to the particular illustrated shapes of regions, but are to include deviations in shapes that result from, for instance, manufacturing. In this manner, regions illustrated in the drawings may be schematic in nature and the shapes of these regions may not reflect actual shapes of regions of a device and, as such, are not necessarily intended to be limiting.

The terms “about” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value.

Unless otherwise defined or implied herein, all terms (including technical and scientific terms) used herein have the same meaning as commonly understood by those skilled in the art to which this disclosure pertains. It will be further understood that terms, such as those defined in commonly used dictionaries, should be interpreted as having a meaning that is consistent with their meaning in the context of the relevant art and the disclosure, and should not be interpreted in an ideal or excessively formal sense unless clearly so defined herein.

As customary in the field, some embodiments are described and illustrated in the accompanying drawings in terms of functional blocks, units, and/or modules. Those skilled in the art will appreciate that these blocks, units, and/or modules are physically implemented by electronic (or optical) circuits, such as logic circuits, discrete components, microprocessors, hard-wired circuits, memory elements, wiring connections, and the like, which may be formed using semiconductor-based fabrication techniques or other manufacturing technologies. In the case of the blocks, units, and/or modules being implemented by microprocessors or other similar hardware, they may be programmed and controlled using software (e.g., microcode) to perform various functions discussed herein and may optionally be driven by firmware and/or software. It is also contemplated that each block, unit, and/or module may be implemented by dedicated hardware, or as a combination of dedicated hardware to perform some functions and a processor (e.g., one or more programmed microprocessors and associated circuitry) to perform other functions. Also, each block, unit, and/or module of some embodiments may be physically separated into two or more interacting and discrete blocks, units, and/or modules without departing from the scope of the disclosure. Further, the blocks, units, and/or modules of some embodiments may be physically combined into more complex blocks, units, and/or modules without departing from the scope of the disclosure.

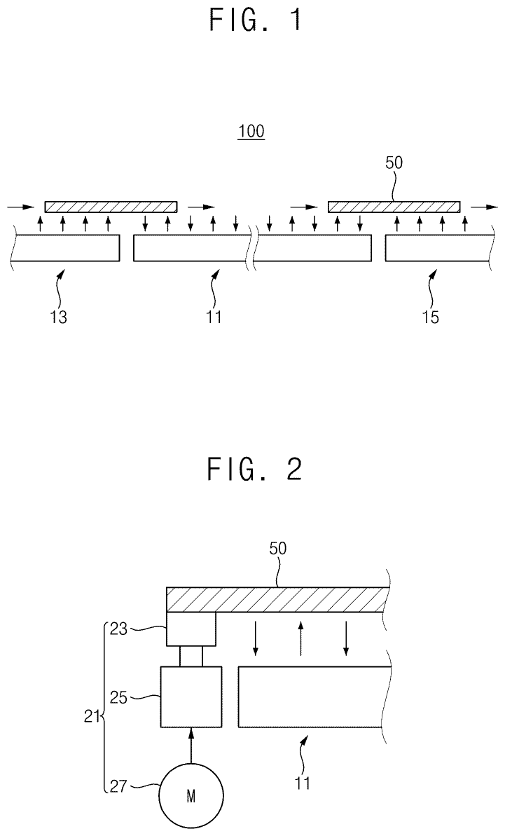

FIG. 1 is a schematic diagram for describing an apparatus for processing substrate according to embodiments.

Referring to FIG. 1, an apparatus for processing substrate 100 according to embodiments may be applied to perform a discharging process of discharging a chemical solution onto a substrate 50 when manufacturing a display element such as OLED, QLED, and/or the like. The discharging process may be mainly performed by discharging a chemical solution such as R, G, B ink, and/or the like onto a substrate. The discharging process of discharging the chemical solution such as R, G, B ink and/or the like may be performed while floating the substrate 50.

The apparatus for processing substrate 100 may be provided with stages 11, 13, and 15 that provide a floating area for floating the substrate when the discharge process is performed. The stages 11, 13, and 15 may include a floating stage 11 provided in a discharge section for discharging a chemical solution onto the substrate 50, a carrying-in stage 13 provided in a carrying-in section for carrying the substrate 50 into the floating stage 11, and a taking-out stage 15 provided in a carrying-out section for taking out the substrate 50 from the floating stage 11. As the carrying-in stage 13 and the carrying-out stage 15 only need to float the substrate 50 at a certain height, the carrying-in stage 13 and the carrying-out stage 15 may be provided to have a structure of floating the substrate by supplying only air. As the floating stage 11 needs to float the substrate 50 at a relatively more accurate height, the floating stage 11 may be provided to have a structure of floating the substrate 50 by supplying a vacuum together with air.

FIG. 2 is a schematic diagram for describing a transfer unit in the apparatus for processing substrate according to embodiments.

Referring to FIG. 2, the apparatus for processing substrate 100 according to embodiments may be provided with a transfer unit 21 for transferring the substrate 50 along the stages 11, 13, and 15.

The transfer unit 21 may be provided to have a structure including a gripping unit 23, a guide rail 25, a driving unit 27, and/or the like. The transfer unit 21 may be provided to be located on one side of the stages 11, 13, and 15, or may be provided to be located on both sides. The gripping unit 23 may be formed to grip an end of the substrate 50 directly or may be provided to vacuum-adsorb the end of the substrate 50. The guide rail 25 may be provided so that the gripping unit 23 may slide along the stages 11, 13, and 15. The guide rail 25 may be provided to have a rail structure extending along the stages 11, 13, and 15. The driving unit 27 may be provided to supply a driving force for the gripping unit 23 to slide along the guide rail 25. An example of the driving unit 27 may be a motor.

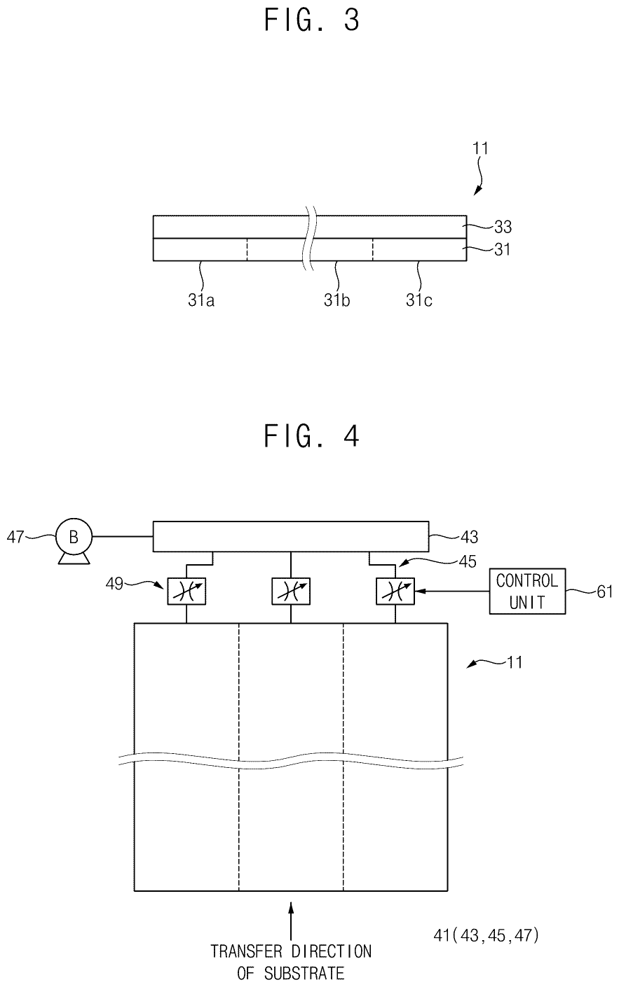

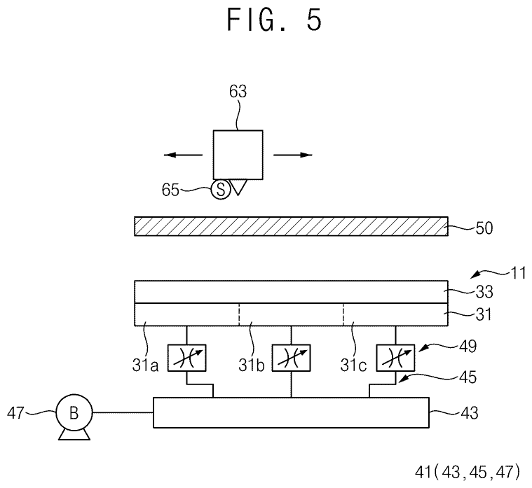

FIG. 3 is a schematic diagram for describing a floating stage in the assembly for floating substrate of the apparatus for processing substrate according to embodiments. FIGS. 4 and 5 are schematic diagrams for describing the assembly for floating substrate of the apparatus for processing substrate according to embodiments.

First, referring to FIGS. 1, and 3, the floating stage 11 in the apparatus for processing substrate 100 according to embodiments may be provided to have a structure including an upper plate 33, a nozzle plate 31, and/or the like.

The upper plate 33 may be provided to face the substrate 50. The nozzle plate 31 may be provided to be located under the upper plate 33. The upper plate 33 may be provided to have a single plate structure.

On the other hand, the nozzle plate 31 may be provided to have a structure divided into at least two portions. The structure divided into at least two portions in the nozzle plate 31 may be formed by dividing a single plate into at least two areas or by combining at least two plates. The nozzle plate 31 may be provided to be divided into at least two portions in a same direction as a transfer direction in which the substrate 50 is transferred during the discharge process. The nozzle plate 31 in this disclosure may be divided into three units in a same direction as the transfer direction of the substrate 50, and may include a first nozzle plate 31a, a second nozzle plate 31b, and a third nozzle plate 31c. That is, the nozzle plate 31 may be divided into the first nozzle plate 31a, the second nozzle plate 31b, and the third nozzle plate 31c. That is, the nozzle plate 31 may include the first nozzle plate 31a, the second nozzle plate 31b, and the third nozzle plate 31c.

Although not shown, a lower plate may be provided to be located under the nozzle plate 31. The upper plate 33 and the nozzle plate 31 may be provided with floating holes for supplying a floating force to the substrate 50. The floating holes may be provided to have a structure in which the nozzle plate 31 and the upper plate 33 communicate with each other. The floating holes in the nozzle plate 31 may be provided to have a structure in which an air flow forms a vortex so that the substrate floating from the floating stage 11 may maintain an equilibrium state, and may be mainly provided to have a cogwheel structure. As the substrate in the floating plate 11 may float by supply of air and vacuum, the floating holes are air holes and vacuum holes.

In addition, referring to FIGS. 1, 4, and 5, the assembly for floating substrate in the apparatus for processing substrate 100 according to embodiments may be provided to have a structure including a floating force supply unit 41, a floating force adjustment unit 49 along, and/or the like, with the floating plate 11.

The floating force supply unit 41 may be provided to have a structure for supplying a floating force for floating the substrate 50 to the upper plate 33 through each of at least two nozzle plates 31. The floating force supply unit 41 may be provided to be connected to air holes among the floating holes formed in the nozzle plate 31. However, the floating force supply unit 41 according to embodiments may be an air supply unit supplying air. The floating force supply unit 41 may be provided to have a structure including an air blower 47 that applies pressure to air and transmits the air, and connection tubes 43 and 45 connecting the air blowers 47 and the air holes. The connection tubes 43 and 45 may include a single tube 43 extending from the air blower 47, and a branch tube 45 branching from the single tube 43 so as to be connected to each of at least two nozzle plates 31. The single tube 43 may be provided to have a structure including a manifold, and the branch tube 47 may be provided to have a structure branched from the manifold in the single tube 43.

Although not shown, the assembly for floating substrate may be provided to have a structure further including a vacuum supply unit because it can be configured to float the substrate 50 from the floating stage 11 by supplying a vacuum together with air. The vacuum supply unit may be provided to have a structure including a vacuum compressor, a connection tube connecting the vacuum compressor and the vacuum holes, and/or the like. In the case of the connection tube for supplying the vacuum, a single tube may be provided to extend from a vacuum compressor, and a branch tube may be provided to branch from a single tube so as to be connected to each of at least two of nozzle plates.

The floating force adjustment unit 49 may be provided to have a structure of adjusting magnitude of a floating force supplied to each of at least two portions of the nozzle plate 31. The floating force adjustment unit 49 may be provided to adjust magnitude of a floating force according to height at which the substrate 50 floats from the floating stage 11. As the floating force adjustment unit 49 should be provided in each of at least two portions of the nozzle plate 31, it should be provided in each of at least two portions of the nozzle plate 31. For example, the floating force adjustment unit 49 may include a first part adjusting magnitude of floating force at the first nozzle plate 31a, a second part adjusting magnitude of floating force at the second nozzle plate 31b, and a third part adjusting magnitude of floating force at the third nozzle plate 31c. The floating force adjustment unit 49 may be provided to have a structure of adjusting magnitude of a floating force supplied to each of at least two portions of the nozzle plate 31 according to floating height at which the substrate 50 floats from the floating stage 11. The floating force adjustment unit 49 may be provided to adjust the floating force supplied to each of at least two portions of the nozzle plate 31 by the floating force supply unit 41, and may be provided in each of the branch tubes 45 in the floating force supply unit 41. An example of the floating force adjustment unit 49 may include a speed controller, and/or the like.

As the assembly for floating substrate is configured to adjust magnitude of the floating force supplied to at least two portions of the nozzle plate 31 according to the floating height of the substrate 50 at least two portions of the nozzle plate 31, the floating force may be uniformly supplied to an entire area of the floating stage 11. For example, as the floating force adjustment unit 49 may include the first part for adjusting the magnitude of the floating force at the first nozzle plate 31a, the second part for adjusting the magnitude of the floating force at the second nozzle plate 31b, and the third part for adjusting the magnitude of the floating force at the third nozzle plate 31c, the magnitude of the floating force supplied to the first nozzle plate 31a, the magnitude of the floating force supplied to the second nozzle plate 31b, and the magnitude of the floating force supplied to the third nozzle plate 31c may be independently adjusted.

The apparatus for processing substrate 100 according to embodiments may be provided with a discharge unit 63 for discharging a chemical solution on the substrate 50 that is transferred along the floating stage 11.

The discharge unit 63 may be provided to have a structure including an inkjet head which discharges a chemical solution such as R, G, B ink, and/or the like, onto the substrate 50 by an inkjet method. The discharge unit 63 may be provided to discharge the chemical solution while moving in a direction perpendicular to a transfer direction of the substrate 50. The discharge unit 60 may be provided to have a structure supported by a support member such as a gantry (not shown) which extends in a direction perpendicular to the transfer direction of the substrate 50. For example, the transfer direction of the substrate and the direction perpendicular to the transfer direction of the substrate may form a plane, and the substrate may include the plane.

Accordingly, the apparatus for processing substrate 100 may be able to perform a chemical solution discharge process in a state in which the floating force is uniformly supplied to the entire area of the floating stage 11 by the assembly for floating substrate, and as a result, it will be possible to prevent process defects caused by varying floating height of the substrate 50 on the floating stage 11.

The apparatus for processing substrate 100 may be provided with a sensing unit 65 for sensing a floating height of the substrate 50 rising from the floating stage 11. The sensing unit 65 should be provided to sense a floating height of the substrate 50 over an entire area of the floating stage 11, that is, an entire area of the nozzle plate 31 divided into at least two portions in real time. An example of the sensing unit 65 may be a confocal sensor, and/or the like. The sensing unit 65 such as the confocal sensor, and/or the like should be configured to scan a beam vertically toward a target, and thus may be provided to be located one a side vertically facing the substrate 50. Accordingly, the sensing unit 65 may be provided on the discharge unit 63 located to face the substrate 50 vertically while moving in a direction perpendicular to the transfer direction of the substrate 50 during the chemical solution discharge process.

The apparatus for processing substrate 100 may be provided with a control unit 61 capable of adjusting magnitude of a floating force based on a sensing result from the sensing unit 65. The control unit 61 may be provided to adjust magnitude of the floating force supplied to each of at least two portions of the nozzle plate 31 based on a sensing result from the sensing unit 65. The control unit 61 may be provided to control the floating force adjustment unit 49.

As described above, the apparatus for processing substrate 100 may be configured to have a structure further including the sensing unit 65 and the control unit 61, so that the floating force can be supplied more evenly to the entire area of the floating stage 11 by the assembly for floating substrate.

Hereinafter, a method for processing substrate according to embodiments will be described. In addition, as the method for processing substrate according to embodiments may be performed using the apparatus for processing substrate of FIGS. 1, 2, 3, 4, and 5, same reference numerals are used for same components, and detailed descriptions thereof will be omitted

First, the substrate 50 is carried in from the carrying-in stage 13 to the floating stage 11. The substrate 50 carried into the floating stage 11 may be in a state of floating from the floating stage 11 by a floating force composed of supply of air and vacuum. In addition, the substrate 50 is transferred along the floating stage 11 using the transfer unit 21, and the chemical solution is discharged on the substrate 50 that is transferred along the floating stage 11 using the discharge unit 63.

In the method for processing substrate of this disclosure, magnitude of the floating force supplied to each of at least two portions of the nozzle plate 31 may be adjusted according to the floating height at which the substrate 50 rises from the floating stage 11. In particular, In the method for processing substrate, the floating force adjustment unit 49 may be controlled to sense the floating height of the substrate 50 floated from the floating stage 11 using the sensing unit 65 and to adjust the magnitude of the floating force supplied to each of at least two portions of the nozzle plate 31 based on the sensing result. However, the magnitude of the floating force supplied to each of at least two portions of the nozzle plate 31 may be adjusted by adjusting supply of air.

Adjusting magnitude of the adjusting force in the method for processing substrate may be performed after the substrate 50 on which the chemical solution has been discharged is carried out from the floating stage 11 and before the substrate 50 on which the chemical solution is to be discharged is carried in to the floating stage 11. That is, the method for processing substrate may be performed by adjusting the floating height of the substrate in at least two portions of the nozzle plate 31 before the substrate 50 is newly carried in based on the floating height of the substrate 50 on which the discharge process is being performed, and then performing the discharge process by carrying in the substrate 50.

Selectively, the magnitude of the floating force may be adjusted by checking the floating height of the substrate 50 from the floating stage 11 in real time. That is, by controlling the floating force adjustment unit 49 based on result of checking the floating height of the substrate 50 in real time, the floating height of the substrate 50 from the floating stage 11 may be adjusted in real time.

In fact, floating height of the substrate using conventional apparatus for processing substrate and floating height of the substrate using the apparatus for processing substrate of this disclosure was confirmed. In addition, floating height of the substrate in nozzle plate divided into three portions was checked for both the conventional apparatus for processing substrate and the apparatus for processing substrate of this disclosure. For convenience, each of the nozzle plates divided into three portions in the conventional apparatus for processing apparatus may also be indicated by the first nozzle plate 31a, the second nozzle plate 31b, and the third nozzle plate 31c.

First, in the conventional apparatus for processing substrate, floating height of the substrate by supplying air having a pressure of about 3.9 kPa to the first nozzle plate 31a, the second nozzle plate 31b, and the third nozzle plate 31c was checked. Floating height (“μm”) of the first plate 31a is confirmed to be about 261, 251, and 230; Floating height (“μm”) of the second plate 31b is confirmed to be about 270, 256, and 256; and floating height (“μm”) of the third plate 31c is confirmed to be about 325, 319, and 297. As a result of confirming the floating height, it was confirmed that maximum floating height (“μm”) is about 325 and minimum floating height (“μm”) is about 230, so deviation is about 95.

In the apparatus for processing substrate of this disclosure that adjusts magnitude of the floating force, the floating height of the substrate was confirmed by supplying air having a pressure of about 3.9 kPa to the first nozzle plate 31a and the second nozzle plates 31b and supplying air having a pressure of about 1.3 kPa to the third plate 31c. The floating height (“μm”) at the first plate 31a was confirmed to be about 269, 263, and 272, and the floating height (“μm”) at the second plate 31b was confirmed to be about 278, 270, and 267, and the floating height (“μm”) at the third plate 31c was confirmed to be about 263, 248, and 245. As a result of confirming the floating height, it was confirmed that maximum floating height (“μm”) is about 278, and minimum floating height (“μm”) is about 245, so deviation is about 33.

The present disclosure can be applied to various display devices. For example, the present disclosure is applicable to various display devices such as display devices for vehicles, ships and aircraft, portable communication devices, display devices for exhibition or information transmission, medical display devices, and the like.

The foregoing is illustrative of embodiments and is not to be construed as limiting thereof. Although a few embodiments have been described, those skilled in the art will readily appreciate that many modifications are possible in the embodiments without materially departing from the novel teachings and advantages of the present inventive concept. Accordingly, all such modifications are intended to be included within the scope of the present inventive concept as defined in the claims. Therefore, it is to be understood that the foregoing is illustrative of various embodiments and is not to be construed as limited to the specific embodiments disclosed, and that modifications to the disclosed embodiments, as well as other embodiments, are intended to be included within the scope of the appended claims.

What is claimed is:

1. An assembly for floating a substrate comprising:
a floating stage including an upper plate facing a substrate and a nozzle plate provided under the upper plate to be divided into at least two portions in a same direction as a transfer direction of the substrate;
a floating force supply unit configured to supply a floating force for floating the substrate to the upper plate through each of the nozzle plate divided into at least two portions; and
a floating force adjustment unit configured to adjust magnitude of a floating force supplied to the at least two portions of the nozzle plate according to floating height at which the substrate is floating from the floating stage.

2. The assembly of claim 1, wherein the floating force supply unit is an air supply unit that supplies the air so that the substrate floats from the floating stage.

3. The assembly of claim 2, further comprising:
a vacuum supply unit configured to supply vacuum to the floating stage so that the substrate can float from the floating stage.

4. The assembly of claim 1, wherein the floating force supply unit includes of branch tubes branched from a single tube to each of at least two portions of the nozzle plate, and the floating force adjustment unit is provided in each of the branch tubes.

5. An apparatus for processing a substrate comprising:
an assembly for floating substrate including a floating stage including an upper plate facing a substrate and a nozzle plate provided under the upper plate to be divided into at least two portions in a same direction as a transfer direction of the substrate, a floating force supply unit configured to supply a floating force for floating the substrate to the upper plate through each of the nozzle plate divided into at least two portions, and a floating force adjustment unit configured to adjust magnitude of a floating force supplied to at least two portions of the nozzle plate according to floating height at which the substrate is floating from the floating stage;
a transfer unit configured to transfer the substrate floating on the floating stage along the floating stage; and
a discharge unit configured to discharge chemical solution on the substrate transferred along the floating stage by the transfer unit.

6. The apparatus of claim 5, wherein the floating force supply unit is an air supply unit that supplies the air so that the substrate floats from the floating stage.

7. The apparatus of claim 6, further comprising:
a vacuum supply unit configured to supply vacuum to the floating stage so that the substrate can float from the floating stage.

8. The apparatus of claim 5, wherein the floating force supply unit includes of branch tubes branched from a single tube to each of at least two portions of the nozzle plate, and the floating force adjustment unit is provided in each of the branch tubes.

9. The apparatus of claim 5, further comprising:
a sensing unit configured to sense floating height at which the substrate is floating from the floating stage; and
a control unit configured to control the floating force adjustment unit to adjust magnitude of a floating force supplied to at least two portions of the nozzle plate based on sensing result from the sensing unit.

10. The apparatus of claim 9, wherein the sensing unit is provided on the discharge unit, and is provided to be located vertically facing the substrate.

11. The apparatus of claim 5, wherein the discharge unit is provided to discharge the chemical solution while moving in a direction perpendicular to a transfer direction of the substrate.

12. The apparatus of claim 5, further comprising:
a carrying-in stage provided at entrance side of the floating stage so that the substrate can be carried into the floating stage; and
a carrying-out stage provided at outlet side of the floating stage so that the substrate can be carried out from the floating stage.

13. The apparatus of claim 12, wherein rise of the substrate in the carrying-in stage and the carrying-out stage are made by supplying air to the carrying-in stage and the carrying-out stage.

14. A method for processing substrate, the method comprising:
floating a substrate from a floating stage including an upper plate facing the substrate and a nozzle plate provided under the upper plate to be divided into at least two portions in a same direction as a transfer direction of the substrate;
transferring the substrate along the floating stage;
discharging chemical solution onto the substrate that is transported along the floating stage; and
adjusting magnitude of a floating force supplied to each of at least two portions of the nozzle plate according to floating height at which the substrate floats from the floating stage.

15. The method of claim 14, further comprising:
sensing the floating height at which the substrate floats from the floating stage, and
wherein the magnitude of the floating force supplied to each of at least two portions of the nozzle plate is adjusted based on sensing result.

16. The method of claim 15, wherein the sensing of the floating height is performed on side of the discharge unit vertically facing the substrate.

17. The method of claim 14, wherein the chemical solution is discharged along a direction perpendicular to the transfer direction of the substrate.

18. The method of claim 14, wherein the adjusting the magnitude of the adjusting force is performed after a substrate on which the chemical solution has been discharged is carried out from the floating stage and before a substrate on which the chemical solution is to be discharged is carried in to the floating stage.

19. The method of claim 14, wherein the substrate is provided to float from the floating stage by supply of air and vacuum, and the magnitude of the floating force is adjusted by adjusting supply of air.

20. The method of claim 19, wherein air to at least two portions of the nozzle plate is supplied through different paths.
